(19) United States
(12) Patent Application Publication
(10) Pub. No.: US 2009/0004364 A1
(43) Pub. Date: Jan. 1, 2009

(54) Method For Protecting New/Used Engine Parts

(76) Inventors: Terry Hollis, Wellington, FL (US); Chris Williams, Lake Worth, FL (US); Gary Prus, Jupiter, FL (US); Jerry Sileo, Palm Beach Gardens, FL (US)

Correspondence Address: MCHALE & SLAVIN, P.A., 2855 PGA BLVD, PALM BEACH GARDENS, FL, 33410, US

(21) Appl. No.: 12/204,463

(22) Filed: Sep. 4, 2008

Related U.S. Application Data
(63) Continuation-in-part of application No. 10/761,765, filed on Jan. 21, 2004, now abandoned.

(51) Int. Cl. C23C 14/54

(52) U.S. Cl. 427/9; 427/580

(57) ABSTRACT

New and used parts of gas and steam turbine engines are protected by imparting a controlled residual compressive stress to given portions of the part and then coated by a CVD or PVD process at low temperatures with layers of TiN or alloys thereof at alternate selective hard and less hardened levels. The protective treatment is particularly efficacious for airfoils of compressor blades/vanes of gas turbine engines and airfoils of airfoils and certain components of steam turbine engines. This method is targeted to reduce erosion, corrosion and stress-corrosion cracking in these parts.

### RELATED APPLICATIONS

This application is a continuation-in-part of application Ser. No. 10/761,765, filed Jan. 21, 2004, the entirety of which is incorporated herein by reference.

### FIELD OF THE INVENTION

This invention relates to the method for protecting new and used components of gas and steam turbine engines and more particularly to the method for protection of the airfoils of new and used blades that are used or to be used in gas turbine power plants powering aircraft and ground installations so as to protect against erosion, corrosion and fatigue and the airfoils of blades and vanes as well as components subjected to erosion, corrosion and fatigue for steam turbine engines.

### BACKGROUND OF THE INVENTION

As is well known in the power plant technology of steam and gas turbine engines, one of the more insidious problems associated with the components of the engine and particularly the rotors, is the erosion, corrosion and fatigue of the engine components that operate in hostile environments and particularly where water is the influence of the corrosion or erosion. Hence, this invention is particularly directed to the airfoils and particularly the compressor blades and vanes of the gas turbine aircraft and ground operated engine and the airfoils and components of the steam turbine engine in areas that are not subjected to super heat, i.e., to areas where water particulate impinge on the surfaces thereof. Needless to say, because of the enormous costs in original and replacement components, like blades, vanes and discs, there is a tremendous need in the industry to provide a suitable method to protect these components from stress corrosion/cracking, erosion and corrosion assisted fatigue. This invention in addition to providing protection to new equipment it also teaches a repair technique that will not only serve to repair the damaged component, but will also add life thereto. As these components are fabricated from different materials certain types of problems arise as a result of their end usage. For example, components fabricated from iron based alloys exhibit corrosion, stress corrosion/cracking and other forms of distress arising out of their operation and maintenance environments. Components made from nickel, cobalt, titanium alloys can exhibit particulate and cavitation erosion when operated at similar environments. These problems have been so pervasive that it has been seen where compressor blades fabricated from martensitic stainless steel (Custom 450, for example) have endured such significant stress occasioned from erosion and subsequent corrosion attacks and failure that the airfoils became liberated from their attachment to its discs resulting in significant damage to the entire turbine assembly.

Another problem with gas turbine engines is inlet fogging or water injection. This addition of water to the inlet of the turbine increases the output power/thermal efficiency of the turbine. This technique not only increases maneuverability of the gas turbine during part load operation, but also decreases the exhaust gas emissions of CO and unburned hydrocarbons by at least half. Fuel efficiency increases can be realized with the use of inlet fogging or water injection. However, water injection and inlet fogging causes airfoil leading edge cavitation erosion. This cavitation erosion results in surface roughening and/or pitting. Fatigue strength capability reductions occur as a result of this roughening and/or pitting, making the affected airfoils susceptible to fatigue cracking and subsequent air foil liberation resulting in significant damage to the gas turbine.

It is pointed out here that while this invention includes the technique of cold working certain areas of the airfoil so as to impart a residual compressive stress, this residual compressive stress is judiciously controlled both in area and depth to assure that the tensile stress is at a predetermined value. In addition, this invention applies to the surface a particular coating that in this combination of cold working the surface and adding layers of coating at low temperatures will provide efficacious protection to these components.

As one skilled in this art will appreciate, the cold working of airfoil surfaces and the like are well known techniques for imparting a tensile strength to resist cracking. A good understanding of tensile stress may be had by referring to U.S. Pat. No. 6,622,570 granted to Prevey, III on Sep. 23, 2003 that teaches the cold working of airfoils by a burnishing operation. It is Prevey's opinion that shot peening is an unacceptable technique for airfoils where a greater depth of compressive stress penetration is required or for parts that require localized or well defined compressive stress regions. However, if a great depth of compressive stress penetration is not required then shot peening is acceptable.

Further, there are a number of methods that are taught in the prior art for coating of airfoils. An example of a protection/repair method is disclosed in U.S. Pat. No. 6,605,160 granted to Hoskin on Aug. 12, 2003 entitled REPAIR OF COATINGS AND SURFACES USING REACTIVE METALS COATING PROCESSES. This patent is primarily concerned with the spot repair of various types of protective coatings as for example PVD, CVD, plasma spray and reactive coatings. This teaching has to be distinguished from the teachings of the present invention where Hoskin teaches reactive coatings where the coatings form a part of the original surface and contains the major constituents and elements of the base metal alloy. In contrast, the present invention is essentially an overlay coating and its chemistry is independent and unique from the base alloy. This is true notwithstanding the fact that the method of forming the final coating product is through the method of reaction of a metal species with a gaseous environment. As one skilled in this technology appreciates, the distinction of the overlay coating and the reactive coating is that the reactive coatings are accomplished through techniques considered to be surface modification methods, namely, ion bombardment, ion substitution, ion plating, gaseous conversion, plasm conversion, etc.

What distinguishes this invention over the hereto known prior art repair/protection techniques is, without limitations, as follows:

1. The method of this invention is a combination of synergistic surface treatments that improve erosion or corrosion or fatigue or stress corrosion cracking/corrosion assisted fatigue distress. The selection of the surface treatments are such as to eliminate or diminish the initiating mechanism that was the cause of the failure.

2. The inventive method includes a surface treatment technique that imparts residual compressive stress and cold works the surface to improve fatigue resistance and stress corrosion, cracking/corrosion assisted fatigue resistance and work hardens the surface to improve erosion resistance. This step in the method is designed to offset any fatigue deficit associated with the application of the coating material as well as attaining the benefits typically provided by adding compressive residual stresses.

3. The substrate is further protected by this inventive method by depositing a film of a hard erosion corrosion and impact resistant material which is designed to mitigate the initiation mechanism. The deposition is applied at a relatively low temperature in order to minimize the relaxation of the compressive residual stresses previously applied as opposed to a high temperature that is typically heretofore used which has an opposite effect.

4. The coating utilized in this protection method is a thin film having a negligible affect on the mass and contour of airfoils and the deposition is by a PVD or CVD technique and the coating consists of the addition of nitride or carbide or both.

In accordance with this invention, airfoils and steam turbine components are protected by a unique method of imparting on and slightly below the surface of the component a residual compressive stress and subsequently thereto, coating that surface with alternate layers of a hard and less hard erosion, corrosion and impact resistant material to form a thin film coating containing a nitride, carbide or combination thereof. The treatment to the protected component does not change the configuration, size and weight thereof and hence, maintains the aerodynamics of the component.

Essentially the method treatment of new blades/vanes and steam turbine components is by the following steps:
1) peen the component;
2) clean/degrease; and
3) coat the surface with layers of relatively hard coating alternating with relatively soft coating at applying these layers at low temperatures.

For repair of blades/vanes and steam turbine components the method is as follows:
1. Clean and/or de-grease;
2. Visually inspect;
3. FPI/MPI (Fluorescent penetrant inspection);
4. Clean and/or de-grease;
5. Blend cracks, blemishes and other indications;
6. Re-inspect by fluorescent penetrant inspect;
7. Clean and/or de-grease;
8. Peen the airfoil;
9. Peen the root;
10. Clean;
11. Apply corrosion resistant layer coating to the blade/vane, component;
12. Apply anti-gallant to the root; and
13. Inspect the finished part

This invention contemplates the protection of different components all of which have different operating criteria and requirements, and while this invention addresses these parameters, the significant difference between heretofore known protection methods is that this inventive method requires the judicious treatment affecting the residual compressive stress of the component and the film coating applied thereto.

### SUMMARY OF THE INVENTION

An object of this invention is to provide a method for protective treatment of new and used airfoils of gas and steam turbine power plants and components of steam turbine power plants where the airfoils affected by erosion, corrosion and fatigue by imparting a residual compressive stress to certain portions of the airfoils and components and coating the surface with layers of relatively hard and soft coating material and applying the coating at relatively low temperatures.

Another object of this invention is the method of protection of new and used components which include the reduction of erosion, corrosion and stress-corrosion cracking in iron base and other alloys and maintain the original mechanical design of these components without introducing any alterations.

A further object of this invention is the method of protection including the steps of imparting selective residual compressive stresses to the gas path surfaces of the blades, vanes and components by a peening operation and applying a multi layer coating consisting of titanium nitride (TiN) and nonstoichiometric TiN deposited onto the surface to a thickness of between 3 microns to 30 microns by cathodic arc deposition (CAD) at low temperatures.

A still further object of this invention is that by virtue of the coating applied to the surface of the airfoils, the surface becomes “non-stick” in nature of the treated surface so that the resulting rejection of foreign debris within the engine leads to performance retention and reduce requirement for “water washing” of the turbine parts. Performance retention is also realizes through reduced surface finish degradation of treated aerodynamic components throughout the life cycle of the turbine.

The foregoing and other features of the present invention will become more apparent from the following description and accompanying drawings.

### BRIEF DESCRIPTION OF THE DRAWINGS

FIG. 1 is a view in elevation of a compressor blade illustrating an example of an engine component that is protected by the method of this invention.

### DETAILED DESCRIPTION OF THE INVENTION

While this invention is shown in its preferred embodiment as being directed to a compressor blade, this is merely an example where this inventive protective method can be utilized and as mentioned above it is preferably utilized to protect blades and vanes from gas turbine engines and blades, vanes and certain components from steam turbine engines subjected to corrosion or erosion or fatigue.

### Method of Repair

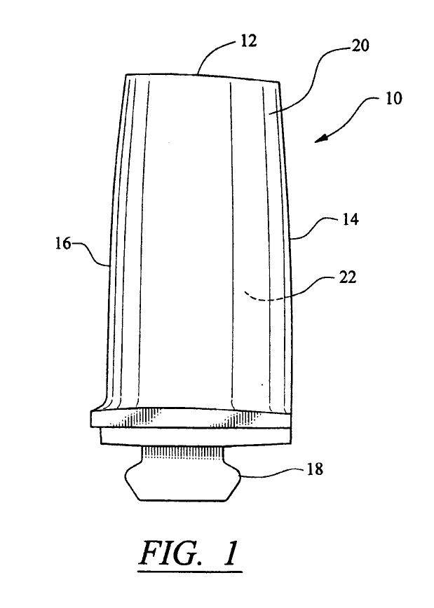

The first portion of this specification will consider this invention from a standpoint that the compressor blade depicted in FIG. 1 is a candidate for repair after being used in a gas turbine engine where reference numeral 10 refers generally to the compressor blade which comprises the tip 12, leading edge 14, trailing edge 16, root and attachment 18, pressure side 20 and suction side 22. For the purposes of describing this invention all the above named portions of the blade except for the root 18 is considered, the airfoil and the pressure side 20 is the gas path surface.

The repair method in accordance with this invention starts with the steps of cleaning and inspecting so that all cracking or indications from non-destructive inspection techniques are removed. The inspection techniques can include any of the following well known techniques such as, visual, fluorescent penetrant inspection (FPI) according to the standards of ASTM E 1417 (type 1, method A to a sensitivity level 4 form a, X-ray, mag particle inspection (MPI), Eddy current or other appropriate techniques. Hence, the repair method will include the following steps prior to imparting the residual compressive stress, clean/de-grease, inspection—visual, inspection—FPI, clean/de-grease, blending of the indications, inspection—FPI, and clean/de-grease. The blending or deburring is done by suitable abrasive and rotary tools, such as flapper wheels, abrasive wheels, Cratex Wheels, or cloth. Tumbling can be utilized in cases where only minor indications need to be removed.

The next step in the method is to impart the residual compressive stress. While it is well known that residual compressive stresses have been applied to airfoils as by shot peening, ceramic peening, burnishing, glass bead peening, laser peening, vibratory finishing, etc. The residual compressive stresses imparted to the surface of the substrate under this repair technique falls within closely controlled parameters. This portion of the surface treatment not only minimizes the tensile stress, the cold working of the surface of the substrate improves the resistance and stress corrosion cracking/corrosion assisted fatigue resistance and work hardens the surface to improve erosion resistance. This technique offsets any fatigue debit associated with the application of the coating material described herein below.

In the repair treatment of the compressor blade 10, the depth and magnitude of the residual compressive stresses for the airfoil portion of the blade is different from the depth and magnitude of the residual compressive stresses of the attachment section. In the airfoil, the residual compressive stresses are imparted by a ceramic shot peening technique where the selective portions of the airfoil section is peened according to AMS 2430 process using ceramic beads which are sized in the range of 0.012 to 0.024 inches. These selected portions are peened to an intensity of 10N. The intensity is measured utilizing Alem test strips “N”, “A”, and “C” as specified in the AMS 2430 process. The process defines the peening intensity as including a numeric value designating the minimum arc height or arc height range in thousandths of an inch in a standard gage length on a test strip totally peened across the width and end to end on one side and a letter designating the type of test strip. For example, “Intensity 10A” indicates an arc height of 0.010 inch on an “A” test strip, measured of the standard gage. If it is desired to specify a tolerance on peening intensity or a basic intensity other than as above, this may be done by specifying either a range of intensity or a basic intensity with a tolerance; thus, an intensity of either 12 to 15N or 12N+/−3, denotes an arc height of 0.012 to 0.015 inch on the “N” test strip. Although absolute stress pressures are not utilized in this process, the stresses of the process can be compared to one another utilizing a standard unit of measure. The leading edge 14 and trailing edge 16 are peened such that the peening fades from a distance of 0.187″ to 0.250″ from the leading edge 14 and the trailing edge 16 to an intensity of 5N to 8N on the leading edge 14 and to an intensity of 5N or less on the trailing edge 16.

The root or attachment portion of the blade is cold worked by a shot peening method that is done according to AMS 2430 using SAE 110-230 steel shot to an intensity of 6-8A over the entire surface that will be in contact with the disk (not shown). Obviously, the peening of the airfoil and attachment sections should be verified by a peen scan or other suitable dye techniques. In addition the peening is accomplished only by automated or mechanized equipment so as to control critical process parameters, namely, pressure, standoff distance, rotational speed, etc. and be repeatable. Almen strips are intended to be used so as to characterize peening process and coverage for the particular component and peening is to be done only with clean, filtered, dry and oil free air.

Once the residual compressive stresses are imparted to the airfoil and root section of the blade, the blade is then cleaned and a corrosion resistance coating is applied to the airfoil. Just as it is important to control the parameters of the resistive compressive stresses, according to this invention, it is abundantly important to control the parameters of, as well as selecting the right materials for the coating for the cold worked surfaces. The peened surfaces need to be free of dirt, oil, or other contaminants and is baked in an air circulating oven for a period of not less than an hour (+/−25° Fahrenheit (F.)).

The areas that are not intended to be coated are masked and the blade is then grit blasted using #150-#240 aluminum oxide grit until the finish of the surface is uniformly matte. The coating is applied to the surface so as to improve erosion, corrosion and oxidation properties and is done at a low temperature so that the previously imparted residual stresses are not jeopardized. Any of the following materials can be used as the coating base material and include chromium, titanium, nickel, vanadium or cobalt alloys and may have alloying elements such as aluminum, cobalt and/or nickel etc. Nitrogen and carbon are incorporated in the plating process to impart erosion and impact resistance to the coating and the coating is preferable done by a PVD or CVD process and done in layer form by intermittently adding the nitrogen or carbon, as described in more detail herein below. The thickness of the coating is controlled to 3 microns to 30 microns. As mentioned earlier, the low temperature range (300 degrees to 350 degrees Fahrenheit) is selected to minimize the relaxation of the compressive residual stresses. This is unlike prior art methods that utilize high temperatures in the coating process which has a deleterious affect on the residual compressive stresses.

The minimal thickness of the coating to the blade 10 as done in accordance to the above method, adds minimal dimension to the airfoil and hence, replicates the airfoil contour and maintains its aerodynamic performance. This is in contrast, for example, to the hereto known repair of components of the steam turbine engine which uses chrome carbide (AMS 7875) applied by a thermal spray process and while this repair works well, it adds significant mass so as to change the aerodynamics as well as adding to the mass of the component.

Certain portions of the blade, like the root, require an anti-gallant coating. This surface is blasted using #220 or finer aluminum oxide grit. The coating is Ensalube-382, Dow 3400 A to a thickness of approximately 0.001″ to 0.003″. The coating is then cured for 2-2.5 hours at 150° F. (+/−25° F.) followed by 2-2.5 hours at 400° F. (+/−25° F.).

### Method of Protection of New Parts

This portion of the specification deals with the method of protecting new parts and the blade depicted in FIG. 1 is utilized for this description. As noted the airfoil section after the manufactured blade is readied to be treated and is cleaned in a suitable manner, selected surfaces of the airfoil are cold worked so as to obtain the desired residual compressive stress, between 5N to 20N, which approximates the proportional limit of the material of the blade or component. Cold working may be done by any suitable peening process, such as shot peening, ceramic peening, glass bead peening, water jet peening and laser shock peening. The trailing edge is masked during this operation reduces the depth of residual compressive stress to this portion of the airfoil. The next step in the method is the coating operation and again the part is cleaned and again masked so as to coat only the airfoil portion of the blade. It is then inserted into a cathodic arc vacuum chamber that is at a low pressure and filled with argon or other non-toxic gas. The chamber is selectively filled with controlled quantities of nitrogen which reacts with the titanium exuded from the titanium electrode of the chamber. The process is done at a relatively low temperature say from 300 degrees Fahrenheit to 350 degrees Fahrenheit, in contrast to heretofore method that process the coating in much higher temperatures. In this manner only the airfoil is coated and by reducing and raising the quantity of nitrogen the hardness of the layers of coating are at different levels. The part is then inspected to assure the coating does not exceed a certain thickness so as to assure that the aerodynamics of the blade.

While the examples described above include coatings applied by a PVD process, a CVD process could likewise be utilized. While the material selected in the above description was a titanium or titanium alloy with a selected amount of nitrogen for different layers, however, other materials such as chromium, nickel, vanadium or cobalt bearing alloys that may have alloying elements such as aluminum, cobalt and nickel may be used. Carbon rather than nitrogen can be used as the alloying element. What has been shown by this invention is a protective treatment of the surface of engine components to not only reduce the erosion, corrosion, stress corrosion, and erosion/corrosion assisted fatigue cracking, it also enhances their performance and durability of these components while maintaining the aerodynamic attributes thereof.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

We claim:

1. A method of protecting unused blades and vanes of gas turbine engines or steam turbine engines or components of steam turbine engines comprising the steps of:
a) cold working a surface of the blade, vane or component to impart a residual compressive stress which approximates the proportional limit of the material of the blade, vane or component;
b) cleansing the surface of the blade, vane or component in step (a);
c) coating the surface of the blade, vane or component cleansed in step (b) with a material selected from the group consisting essentially of titanium, TiN, a chromium alloy, a nickel alloy, a vanadium alloy and a cobalt alloy by a cathodic arc deposition at temperatures in the range of from 300 degrees to 350 degrees Fahrenheit to obtain layers of different hardness wherein the total thickness of all the layers is generally between 3 microns to 30 microns.

2. The method of claim 1 wherein said alloying elements of the coating materials are selected from the group consisting essentially of aluminum, cobalt and nickel.

3. The method of claim 1 wherein the cold working is selected from the group consisting essentially of shot peening, ceramic peening, glass bead peening, water jet-peening, and laser peening.

4. The method as claimed in claim 1 further including the step of:
d) inspecting the blades, vanes or components to insure the thickness of the coating material is within the acceptable limits.

5. A method of repairing used blades or vanes of gas or steam turbine engines or components of steam turbine engines to protect against erosion, corrosion and fatigue comprising the steps of:
a) cleaning and/or de-greasing the used blades, vanes or components;
b) inspecting the used blades, vanes or components from step (a);
c) cleaning and/or de-greasing the used blades, vanes or components;
d) blending cracks, blemishes and other defects of the used blades, vanes or components;
e) inspecting by fluorescent penetrant inspection the used blades, vanes or components;
f) cleaning and/or de-greasing the used blades, vanes or components;
g) cold working the surface of the blades or vanes or the surface of the component to impart a residual compressive stress which approximates the proportional limit of the material of the blade, vane or component;
h) cleaning the used blades, vanes or components;
i) coating the surface of the parts cleaned in step (h) with a material selected from the group consisting essentially of titanium, TiN, a chromium alloy, a nickel alloy, a vanadium alloy and a cobalt alloy by a cathodic arc deposition at temperatures in the range of from 300 degrees to 350 degrees Fahrenheit to obtain layers of different hardness wherein the total thickness of all the layers is generally between 3 microns to 30 microns.

6. The method of claim 5 wherein the cold working in the step (g) is by ceramic bead peening.

7. The method of claim 5 wherein said alloying elements of the coating materials are selected from the group consisting essentially of aluminum, cobalt and nickel.

8. The method of claim 5 wherein the cold working is selected from the group consisting essentially of shot peening, ceramic peening, glass bead peening, water jet peening, and laser peening.

9. The method of claim 5 further including the step of:
j) inspecting the finished blades, vanes or components to insure the thickness of the coating material is within the acceptable limits.
